(19) United States
(12) Patent Application Publication
(10) Pub. No.: US 2013/0075850 A1
(43) Pub. Date: Mar. 28, 2013

(54) FLIP-CHIP BONDED IMAGER DIE

(71) Applicants: Timothy Patrick Patterson, Mission Viejo, CA (US); Tim J. Moran, Sunnyvale, CA (US); Craig W. Forrest, Mission Viejo, CA (US)

(72) Inventors: Timothy Patrick Patterson, Mission Viejo, CA (US); Tim J. Moran, Sunnyvale, CA (US); Craig W. Forrest, Mission Viejo, CA (US)

(21) Appl. No.: 13/589,676

(22) Filed: Aug. 20, 2012

Related U.S. Application Data
(60) Provisional application No. 61/525,372, filed on Aug. 19, 2011.
(60) Provisional application No. 61/540,258, filed on Sep. 28, 2011.

(51) Int. Cl. H01L 31/0232; H01L 31/024; H01L 27/146

(52) U.S. Cl. CPC H01L 31/0232; H01L 27/146; H01L 31/024
USPC 257/432

(57) ABSTRACT

An image sensor includes an imager die, a circuit board, and an optical layer. The circuit board is flip-chip bonded to the imager die. The optical layer is adhered to the circuit board and includes a first portion configured to refract light differently than a second portion. Both the first portion and the second portion are integrally formed with the optical layer.

### CROSS-REFERENCE TO RELATED APPLICATIONS

This application claims priority to U.S. Provisional Patent Application Ser. No. 61/525,372, filed on Aug. 19, 2011, the contents of which are hereby incorporated by reference in their entirety.

### BACKGROUND

Image sensors are electronic devices that convert optical images into digital signals and are often used with digital cameras. In general, some image sensors include an array of photodetectors that capture light and outputs a representative signal. Some types of image sensors include charge coupled device (CCD) sensors and complementary metal-oxide-semiconductor (CMOS) sensors.

### BRIEF DESCRIPTION OF THE DRAWINGS

FIG. 1 illustrates a cross-sectional view of an exemplary image sensor.

FIG. 2 illustrates an exemplary imager die that may be used in the image sensor of FIG. 1.

FIG. 3 illustrates an exemplary circuit board that may be used in the image sensor of FIG. 1.

FIG. 4 illustrates a cross-sectional view of another exemplary image sensor.

FIG. 5 illustrates possible dimensions of various components of the image sensor.

### DETAILED DESCRIPTION

An exemplary image sensor includes an imager die, a circuit board, and an optical layer. The circuit board is flip-chip bonded to the imager die. The optical layer is adhered to the circuit board and has a first portion configured to refract light differently than a second portion. Both the first portion and the second portion are integrally formed with the optical layer. In one possible implementation, the image sensor may further include a stiffener disposed between the circuit board and to the optical layer. In some instances, the circuit board may be formed from a flexible material and include a plurality of bumps that are configured to bond to bonding pads on the imager die during the flip-chip bonding process.

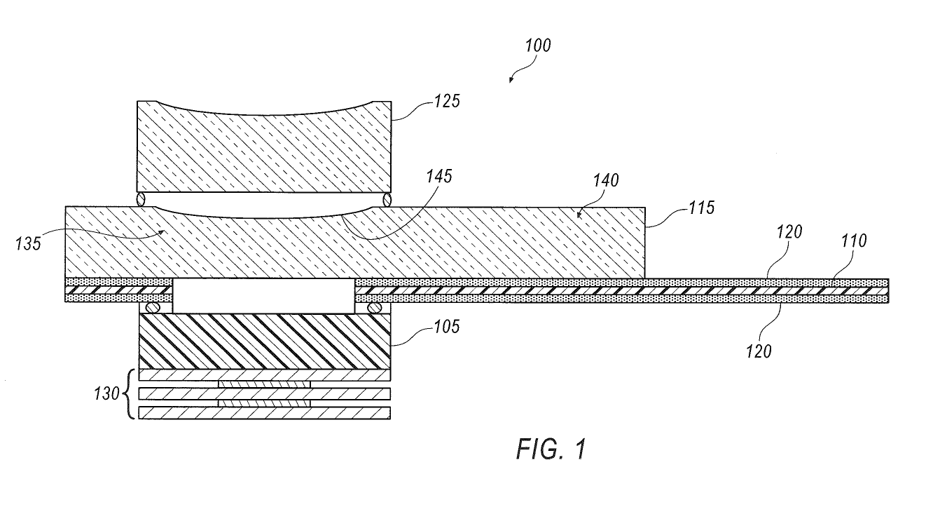

FIG. 1 illustrates an exemplary image sensor 100. The image sensor 100 may take many different forms and include multiple and/or alternate components and facilities. While an exemplary image sensor 100 is shown in FIG. 1, the exemplary components illustrated in the Figures are not intended to be limiting. Indeed, additional or alternative components and/or implementations may be used. Although the drawings represent the various examples, the drawings are not necessarily to scale and certain features may be exaggerated to better illustrate and explain an innovative aspect of an example.

As illustrated in FIG. 1, the image sensor 100 includes an imager die 105, a circuit board 110, an optical layer 115, at least one adhesive layer 120, an optical lens 125, and a heat sink 130.

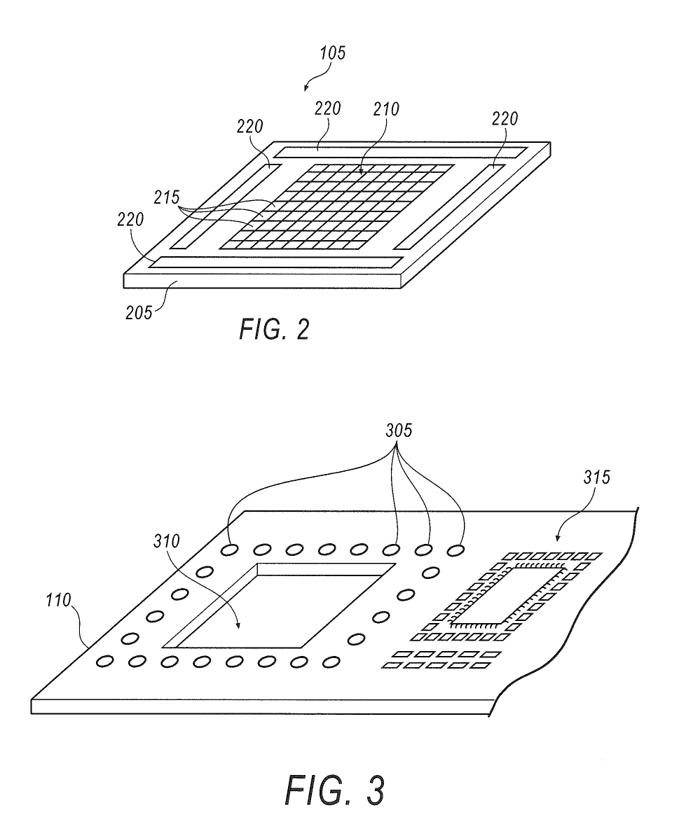

The imager die 105 may include an integrated circuit die formed from a semiconductor material and having a fabricated circuit. In one exemplary approach, the imager die 105 may take the form of a complementary metal-oxide-semiconductor (CMOS) active pixel sensor. An example of the imager die 105 is discussed below with reference to FIG. 2.

The circuit board 110, which may be flip-chip bonded to the imager die 105, may include a printed circuit board 110 configured to support various types of surface mount technology, such as chips, resistors, capacitors, etc. The circuit board 110 may further include conductive pathways, also called traces, connecting various components. The circuit board 110 defines an opening to allow light to pass to the imager die 105. In one possible approach, the circuit board 110 is formed from a flexible material and has a thickness of approximately 0.5 mils to 2 mils. An example circuit board 110 is discussed in greater detail below with reference to FIG. 3.

The optical layer 115 may be adhered to the circuit board 110. In one possible implementation, the optical layer 115 may include glass, a transparent ceramic or plastic, or any other material that is generally transparent to visible light. The optical layer 115 may have a first portion 135 and a second portion 140, each configured to refract light differently. Both the first portion 135 and second portion 140 may be integrally formed with the optical layer 115. As illustrated, the first portion 135 is optically aligned with the image die. The first portion 135 may define an integrally formed lens 145 configured to direct light to the imager die 105. The first portion 135 may further include or define a filter to only allow light having certain characteristics (e.g., wavelength, etc.). The filter may be disposed on the first portion 135 along an optical path between the first portion 135 and the imager die 105, or alternatively, the first portion 135 may be formed from a material that can filter certain wavelengths of light.

Adhesive layers 120 may be used to attach various components of the image sensor 100 to one another. As illustrated, a first adhesive layer 120 may be used to adhere the circuit board 110 to the optical layer 115, and in particular, at least the second portion 140 of the optical layer 115. Another adhesive layer 120 may be used to further help adhere the imager die 105 to the circuit board 110.

The optical lens 125, different from the integrally formed lens 145, may be disposed on the optical layer 115. As illustrated, the optical lens 125 is optically aligned with the integrally formed lens 145 and is configured to direct visible light toward the imager die 105 through the first portion 135 of the optical layer 115. In one possible implementation, the optical lens 125 is disposed on the optical layer 115 via an ultraviolet cure bond using, e.g., a 6-axis or precise feature alignment process.

The heat sink 130 may be disposed on the imager die 105 and include any device configured to dissipate heat generated during operation of the image sensor 100. In one possible approach, the heat sink 130 may include a plurality of fins that draw heat generated by the imager die 105. Airflow through the fins removes heat from the image sensor 100. Alternatively, as illustrated, the heat sink 130 may have a bobbin-like configuration. Specifically, the heat sink 130 may have generally circular sections stacked upon one another, each section having a different radius than the adjacent sections. In one possible implementation, the heat sink 130 may include a thermally conductive liquid or gel to help dissipate heat generated by the imager die 105 or other components used in accordance with the image sensor 100. An example of the thermally conductive liquid may include chlorofluorocarbon.

FIG. 2 illustrates features and components of an exemplary imager die 105. The imager die 105, as illustrated, includes a support substrate 205, a photodetector array 210 with a plurality of photodetectors 215, and multiple bonding pads 220. The imager die 105 may include other components not illustrated in FIG. 2.

The photodetector array 210 is disposed on the support substrate 205. The photodetector array 210 includes a plurality of photodetectors 215 arranged in rows and columns. Each photodetector 215 is configured to generate electrical signals consistent with light received. Although not illustrated, other electronic components, such as amplifiers, resistors, etc., may be used in conjunction with the photodetector array 210.

The bonding pads 220 may be formed from, e.g., aluminum, gold, solder, silver, epoxy, or an anisotropic conductive film and may facilitate the flip-chip bonding process used to connect the imager die 105 to the circuit board 110. The bonding pads 220 may be configured to adhere to corresponding sections of the circuit board 110 through, e.g., a thermosonic bonding or soldering process.

FIG. 3 illustrates features and components of an exemplary circuit board 110. In one possible approach, the circuit board 110 may be formed from a flexible material and have at least one dimension larger than the imager die 105. For instance, the circuit board 110 and imager die 105 may have substantially the same width, but the circuit board 110 may have a longer length. The circuit board 110 illustrated in FIG. 3 includes a plurality of bumps 305, an aperture 310, and surface mounted technology components 315.

The bumps 305 may be formed from a material configured to facilitate the flip-chip bonding between the circuit board 110 and the imager die 105. For instance, the bumps 305 may be formed from various materials such as gold, silver, solder, epoxy, or an anisotropic conductive film. The bumps 305 may be configured to align with the bonding pads 220 of the imager die 105 during the flip-chip bonding process. The bumps 305 may bond to the bonding pads 220 following a thermosonic bonding or soldering process. Once bonded, the bumps 305 provide an electrical connection between the imager die 105 and the circuit board 110. Traces (not shown) may allow electrical signal to travel from the imager die 105 to the surface mount technology components on the circuit board 110.

The aperture 310 defined by the circuit board 110 may allow light to pass to the imager die 105, and particularly, to the photodetector array 210. The aperture 310 may be optically aligned with the first portion 135 of the optical layer 115, which as discussed above defines an integrally formed lens 145, and the optical lens 125.

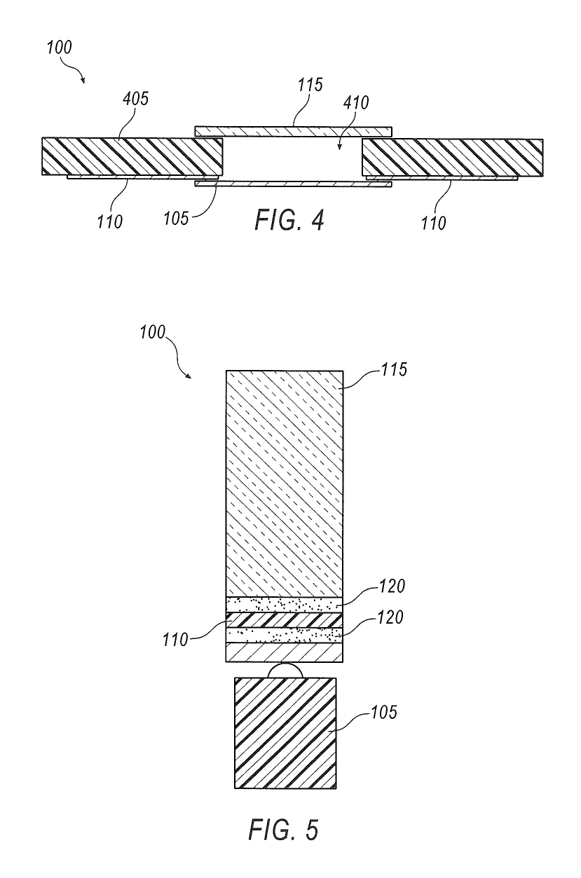

FIG. 4 illustrates an exemplary cross-sectional view of a different image sensor 100. In the image sensor 100 of FIG. 4, a stiffener 405 is adhered to the circuit board 110 and the optical layer 115. The stiffener 405 may be configured to provide structural support to the image sensor 100. In one possible approach, the stiffener 405 may be formed from a metal, an FR-4 grade glass-reinforced epoxy laminate sheet, or any other material configured to structurally support at least a portion of the circuit board 110. Although not illustrated in FIG. 4, an adhesive layer 120 (see FIG. 1) may be disposed between the stiffener 405 and the circuit board 110. The stiffener 405 defines an opening 410 that is optically aligned with the optical path from the optical layer 115 to the imager die 105. This way, the stiffener 405 allows light to pass from the first portion 135, including the integrally formed lens 145, of the optical layer 115 to the photodetector array 210 of the imager circuit.

FIG. 5 is a cross-sectional view that illustrates example thicknesses of some of the components of the image sensor 100. The dimensions presented in FIG. 5 are examples only. As illustrated, the optical layer 115 may have a thickness of approximately 16 mils and the imager die 105 may have a thickness of approximately 8 mils. The two adhesive layers 120 may each have a thickness ranging from approximately 0.5 mils to 2 mils. Likewise, the circuit board 110 may have a thickness of approximately 0.5 mils to 2 mils. The bonding layer may have a thickness of approximately 0.2 mils to 2 mils. Each bump 305, prior to the flip-chip bonding process, may have a thickness of approximately 0.5 mils to 2 mils. The bump 305 may also be approximately 1.5 mils to 6 mils wide.

In general, the image sensor may incorporate computing systems and/or devices that generally include computer-executable instructions, where the instructions may be executable by one or more computing devices such as those listed above. Computer-executable instructions may be compiled or interpreted from computer programs created using a variety of programming languages and/or technologies, including, without limitation, and either alone or in combination, Java™, C, C++, Visual Basic, Java Script, Perl, etc. In general, a processor (e.g., a microprocessor) receives instructions, e.g., from a memory, a computer-readable medium, etc., and executes these instructions, thereby performing one or more processes, including one or more of the processes described herein. Such instructions and other data may be stored and transmitted using a variety of computer-readable media.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random access memory (DRAM), which typically constitutes a main memory. Such instructions may be transmitted by one or more transmission media, including coaxial cables, copper wire and fiber optics, including the wires that comprise a system bus coupled to a processor of a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

1. An image sensor comprising:
an imager die;
a circuit board flip-chip bonded to the imager die;
an optical layer adhered to the circuit board and having a first portion configured to refract light differently than a second portion, wherein both the first portion and the second portion are integrally formed with the optical layer.

2. The image sensor of claim 1, wherein the first portion is optically aligned with the imager die.

3. The image sensor of claim 1, further comprising a lens disposed on the optical layer and optically aligned with the first portion.

4. The image sensor of claim 3, wherein the lens is disposed on the optical layer via an ultraviolet cure bond.

5. The image sensor of claim 1, further comprising an adhesive layer disposed between the optical layer on the circuit board.

6. The image sensor of claim 1, further comprising a heat sink disposed on the imager die.

7. The image sensor of claim 1, wherein the circuit board includes a flexible circuit board.

8. The image sensor of claim 1, wherein the circuit board has a thickness of approximately 0.5 mil to 2 mil

9. The image sensor of claim 1, wherein the circuit board includes a trace having a thickness of approximately 0.2 mil to 2 mil.

10. An image sensor comprising:
an imager die;
a circuit board flip-chip bonded to the imager die;
a stiffener adhered to the circuit board;
an optical layer adhered to the stiffener and having a first portion configured to refract light differently than a second portion, wherein both the first portion and the second portion are integrally formed with the optical layer.

11. The image sensor of claim 10, wherein the stiffener defines an opening configured to allow light to pass from the first portion of the optical layer to the imager die.

12. The image sensor of claim 10, further comprising a lens disposed on the optical layer and optically aligned with the first portion.

13. The image sensor of claim 10, wherein the circuit board includes a flexible circuit board.

14. The image sensor of claim 10, wherein the stiffener is formed at least in part from a metal or an FR-4 grade glass-reinforced epoxy laminate sheet.

15. An image sensor comprising:
an imager die having a bonding pad;
a flexible circuit board flip chip bonded to the imager die, wherein the flexible circuit board includes a plurality of bumps bonded to the bonding pad of the imager die;
an optical layer adhered to the flexible circuit board and having a first portion configured to refract light differently than a second portion, wherein both the first portion and the second portion are integrally formed with the optical layer.

16. The image sensor of claim 15, wherein the bonding pad includes aluminum, gold, solder, silver, epoxy, or an anisotropic conductive film.

17. The image sensor of claim 15, wherein the plurality of bumps include aluminum, gold, solder, silver, epoxy, or an anisotropic conductive film.

18. The image sensor of claim 15, further comprising a lens disposed on the optical layer and optically aligned with the first portion.

19. The image sensor of claim 15, further comprising a heat sink disposed on the imager die.

20. The image sensor of claim 15, wherein the optical layer includes glass, transparent ceramic, or plastic.
